(19) United States
(12) Patent Application Publication
(10) Pub. No.: US 2026/0333749 A1
(43) Pub. Date: Oct. 22, 2026

(54) CYLINDRICAL VERTICAL TRANSISTOR WITH SURROUNDING GATE

(71) Applicant: Taiwan Semiconductor Manufacturing Company, Ltd., Hsinchu (TW)

(72) Inventors: Chen-Jun Wu, Hsinchu City (TW); Chieh-Fang Chen, Hsinchu County (TW); Yu-Chien Chiu, Hsinchu County (TW); Ya-Yun Cheng, Taichung City (TW); Chih-Yu Chang, New Taipei City (TW); Chien-Hao Huang, Hsinchu City (TW); Katherine H. Chiang, New Taipei City (TW)

(21) Appl. No.: 19/185,849

(22) Filed: Apr. 22, 2025

(51) Int. Cl. H10D 30/63; G11C 5/06; H10D 30/01; H10D 62/17; H10D 62/80; H10D 64/27

(52) U.S. Cl. CPC H10D 30/63; G11C 5/06; H10D 30/025; H10D 62/292; H10D 62/875; H10D 64/514; H10D 64/519

(57) ABSTRACT

A first metal feature is disposed over a semiconductor substrate, and a second metal feature is disposed over the first metal feature. A cylindrical oxide region has a central axis that extends perpendicularly between an upper surface of the first metal feature and a lower surface of the second metal feature. A channel structure is disposed between the first metal feature and the second metal feature. The channel structure includes a base portion and a sleeve portion. The base portion separates the first metal feature from the cylindrical oxide region, and the sleeve portion extends from an edge region of the base portion to the second metal feature. The sleeve portion concentrically surrounds the cylindrical oxide region. A cylindrical gate oxide concentrically surrounds the channel structure. A gate electrode concentrically surrounds the cylindrical gate oxide. The cylindrical gate oxide separates the gate electrode from the channel structure.

### BACKGROUND

Memory density is the amount of data that can be stored in a given amount of space (so called “footprint”) on an integrated circuit or other data storage medium. Memory density has increased exponentially over the last several decades. This is due to the demand for more storage capacity in modern electronics and the technical capabilities to pack more data onto a chip. This increase has been a significant factor in the ever-increasing functionality for modern electronics, such as smart phones, computers, smart watches, automobiles, industrial control systems, and others.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1A illustrates a three-dimensional perspective view of some embodiments of an integrated circuit including a memory cell having a vertical transistor according to some aspects of the present disclosure.

FIG. 1B illustrates a schematic view of some embodiments of a memory cell consistent with FIG. 1A.

FIG. 2 illustrates a cross-sectional view of some embodiments of the integrated circuit consistent with FIG. 1A.

FIGS. 3A-3C illustrate various top views taken at different depths of a vertical transistor that has a circular channel and that is consistent with FIG. 2.

FIGS. 4A-4C illustrate various top views taken at different depths of a vertical transistor that has an oval-shaped channel and that is consistent with FIG. 2.

FIG. 5 illustrates another cross-sectional view of some embodiments of the integrated circuit consistent with FIG. 1A.

FIGS. 6A-6C illustrate various top views taken at different depths of a vertical transistor that has a circular channel and that is consistent with FIG. 5.

FIGS. 7A-7C illustrate various top views taken at different depths of a vertical transistor that has an oval-shaped channel and that is consistent with FIG. 5.

FIG. 8 illustrates a three-dimensional perspective view of some embodiments of an integrated circuit including a memory cell having a vertical transistor, where a memory element of the memory cell is above the vertical transistor and a bit-line of the memory cell is below the vertical transistor.

FIG. 9A illustrates a three-dimensional perspective view of some embodiments of an integrated circuit including a memory cell where a first metal feature has tapered outer sidewalls.

FIG. 9B illustrates a cross-sectional view of some embodiments consistent with FIG. 9A.

FIG. 10A illustrates a three-dimensional perspective view of some embodiments of an integrated circuit including a memory cell that includes a channel protection layer.

FIG. 10B illustrates a cross-sectional view of some embodiments consistent with FIG. 10A.

FIG. 11 illustrates a top view of a portion of an array of memory cells in accordance with some embodiments of the present disclosure.

FIG. 12 illustrates a top view of a portion of an array of memory cells in accordance with some embodiments of the present disclosure.

FIG. 13 illustrates a top view of a portion of an array of memory cells in accordance with some embodiments of the present disclosure.

FIG. 14 illustrates a portion of an array of memory cells that are organized into multiple banks with global word-lines extending between the banks in accordance with some embodiments of the present disclosure.

FIG. 15A illustrates a three-dimensional perspective view of some embodiments of an integrated circuit including a memory cell that includes a global word-line.

FIG. 15B illustrates a cross-sectional view of some embodiments consistent with FIG. 15A.

FIG. 16 illustrates a series of cross-sectional views that collectively illustrate some embodiments of a method of forming an integrated chip having a vertical transistor.

FIG. 17 illustrates a series of cross-sectional views that collectively illustrate other embodiments of a method of forming an integrated chip having a vertical transistor.

FIGS. 18-32 illustrate a series of three-dimensional and/or cross-sectional views that collectively illustrate some embodiments of a method of forming an integrated chip with a memory device having vertical transistors.

FIG. 33 illustrates a flow diagram of some embodiments of a method of forming an integrated chip with a memory device having vertical transistors.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Conventional semiconductor memories include memory cells that each store one or more bits of data. A conventional memory cell includes a lateral access transistor that allows access to a memory element, which stores a bit of digital data. The lateral access transistor includes a source, a drain, and a channel that are disposed in a semiconductor substrate, wherein the channel laterally separates the source and drain. A gate electrode extends laterally over the channel. As feature sizes shrink for successive generations of technology, lateral access transistors also shrink to have a smaller “footprint”, thereby enabling an increase in memory density so more bits can be stored per unit area on the chip. However, a length of the channel between source and drain can only shrink so much before undesirable leakage occurs between the source and drain.

Therefore, some aspects of the present disclosure provide for a memory cell having a vertical access transistor. In this vertical access transistor, the source and drain are stacked vertically over one another and are separated from one another by a vertical channel structure. Consequently, because the channel structure is vertical, it can be made “taller” while still keeping a small lateral footprint on the integrated circuit. Thus, the use of the vertical access transistor enables a vertical channel structure that can still be of sufficient length to limit undesirable current leakage, while also enabling extremely high memory density.

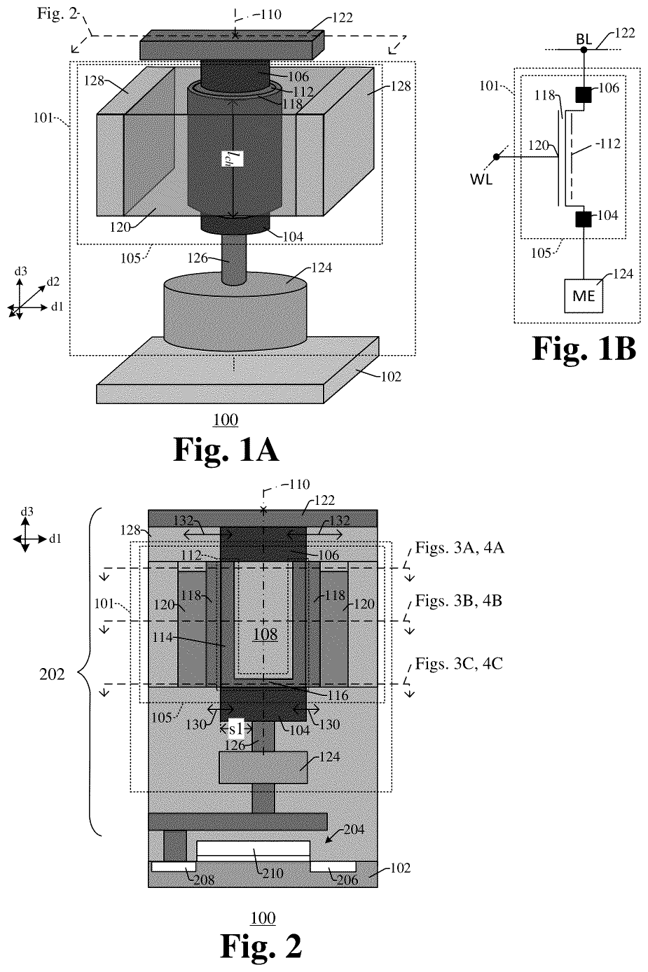

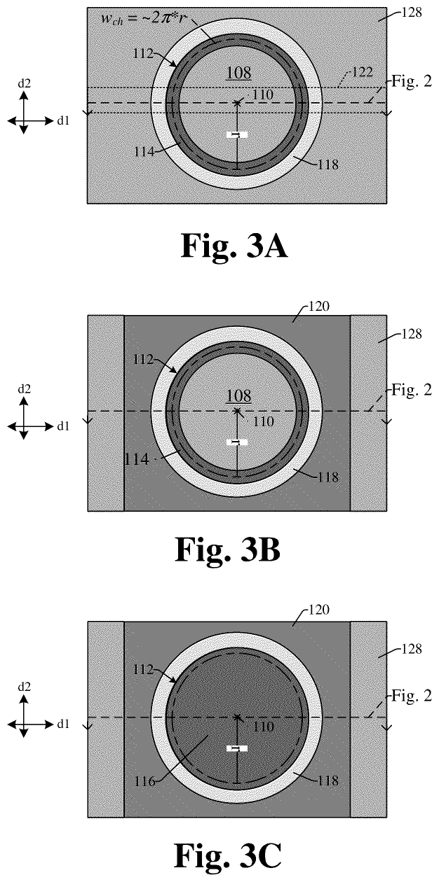

FIG. 1A illustrates a three-dimensional perspective view of some embodiments of an integrated circuit that includes a memory cell 101 according to some aspects of the present disclosure. FIG. 1B shows a corresponding schematic diagram of the memory cell 101, and FIG. 2 shows a cross-sectional view of FIG. 1A. FIGS. 1A, 1B, and 2 are now described concurrently. As can be seen in these figures, the memory cell 101 includes a vertical access transistor 105 and a memory element 124. The memory element 124 is configured to store a bit (or multiple bits) of digital data, and the access transistor 105 is configured to allow selective access to the memory element 124 so that data can be written to and read from the memory element 124. A conductive bit-line (BL) 122 is coupled to the memory element 124 via source/drain regions of the access transistor 105. A word-line (WL) 120 is coupled to the gate of the access transistor 105, and the gate is separated from a channel structure 112 of the transistor by a gate oxide 118.

Thus, during operation, the word-line 120 can be activated to put the channel structure 112 into a conductive state, such that the bit-line 122 is operably coupled to the memory element 124. The word-line 120 can also be deactivated to put the channel structure 112 into a highly resistive and/or “open” state, such that the bit-line 122 is disconnected from the memory element 124. Thus, when the word-line is activated (e.g., magnitude of the gate voltage is greater than a threshold voltage of access transistor), data can be written to and/or read from the memory element 124 via bit-line 122; whereas when the word-line 120 is deactivated (e.g., magnitude of the gate voltage is less than the threshold voltage of access transistor), the memory element 124 retains its present data state and is not accessed.

The memory element 124 can take various forms, but often is arranged within a back end of line (BEOL) interconnect structure 202 of the integrated circuit. Thus, as can be seen in FIG. 2, the memory element can be arranged within an inter-layer dielectric (ILD) structure 128, and/or between conductive metal lines of the BEOL interconnect structure over an upper surface of the substrate 102. The memory element 124 can correspond to a resistive random access memory (RRAM), magnetic random access memory MRAM, phase change random access memory (PCRAM), ferroelectric tunnel junction (FTJ) memory, and/or a metal-insulator metal (MIM) capacitor in the BEOL interconnect structure, or can even be a trench capacitor disposed in the semiconductor substrate 102, among others.

As shown in FIG. 1A's three-dimensional perspective view and FIG. 2's cross-sectional view, the memory cell 101 is arranged over a semiconductor substrate 102. The access transistor 105 includes a first metal feature 104, which can act as the first source/drain region of access transistor. The access transistor 105 also includes a second metal feature 106 that is stacked vertically over the first metal feature 104 and which can act as a second source/drain region of access transistor. In some embodiments, the first and second metal features 104, 106 can comprise a metal, such as copper, aluminum, tungsten, titanium, nickel, and/or or tantalum.

A cylindrical oxide region 108, which may also be referred to as a dielectric core, has a central axis 110 that extends perpendicularly between an upper surface of the first metal feature 104 and a lower surface of the second metal feature 106. The cylindrical oxide region 108 can be or comprise silicon dioxide, but can also be a high-k dielectric, a low-k dielectric, or another insulating material.

The channel structure 112 is generally cylindrical and extends vertically between the first and second metal features 104, 106. The channel structure 112 is disposed between the upper surface of the first metal feature 104 and the lower surface of the second metal feature 106. The channel structure 112 includes a base portion 116 and a sleeve portion 114, where the sleeve portion 114 concentrically surrounds the cylindrical oxide region 108 about the central axis 110. The base portion 116 separates the upper surface of the first metal feature 104 from a lower surface of the cylindrical oxide region 108. The sleeve portion 114 extends from an edge region of the base portion 116 to the lower surface of the second metal feature 106. The sleeve portion 114 concentrically surrounds the cylindrical oxide region 108 when viewed from a top view (see e.g., FIGS. 3A-3B). In some embodiments, the channel structure 112 can be or comprises indium tungsten oxide (IWO), indium tin oxide (ITO), indium gallium zinc oxide (IGZO), or another semiconductor material.

The gate oxide 118, which is also typically cylindrical, concentrically surrounds the channel structure 112 when viewed from the top view (See e.g., FIGS. 3A-3C). The gate oxide 118 can be or comprise silicon dioxide or a high-k material, such as hafnium silicate, zirconium silicate, hafnium dioxide, or zirconium dioxide.

The gate electrode 120 laterally and/or concentrically surrounds the cylindrical gate oxide 118 when viewed from the top view. The gate oxide 118 separates the gate electrode 120 from the channel structure 112. The gate electrode 120 can be or comprise a metal, such as copper, aluminum, tungsten, titanium, nickel, and/or or tantalum. In other embodiments, the gate electrode 120 can be or comprise doped polysilicon or another conductive material.

The bit-line 122 is disposed over the second metal feature 106 and extends generally in a first direction (d1). The word-line 120 is coupled to and/or corresponds to the gate electrode and extends generally in a second direction (d2) that is perpendicular to the first direction, d1. The first and second metal features 104, 106 are vertically spaced apart from one another and separated by the channel region in a third direction (d3), which is perpendicular to the first and second directions and normal to an upper surface of the substrate 102. Thus, the memory cell 101 includes a vertical channel structure 112 that allows for a long channel length (l_{ch}) in a small footprint on the integrated circuit. Thus, this architecture enables extremely high memory density, while still providing relatively high read/write currents for fast read/write access times.

As shown in FIG. 2, in some embodiments, one or more semiconductor devices, such as a transistor 204 can be disposed in or on the substrate 102. For instance, the transistor 204 includes source/drain regions 206, 208 in the substrate, and a gate electrode 210. Further, the memory element 124 is coupled to the first metal feature 104 though a via 126, and is arranged between the first metal feature 104 and the substrate 102. The bit-line 122 is arranged over the second metal feature 106.

The first metal feature 104 can have outer sidewalls that are aligned with outer sidewalls of the base portion 116 of the channel structure. However, in other embodiments, the first metal feature 104 can be wider to extend partially beneath the gate oxide 118, or can be narrower to have a width and/or diameter that is less than that of the base portion 116 of the channel structure. (See arrows 130 showing some ways in which the outer sidewalls of the first metal feature 104 can vary.) When the outer sidewalls of the first metal feature 104 are aligned with the outer sidewalls of the base portion 116 as illustrated, it is advantageous in that a good contact with low resistance is provided between 116 and 104. Similarly, the second metal feature 106 can have outer sidewalls that are aligned with outer sidewalls of the sleeve portion 114 of the channel structure as illustrated, but the second metal feature 106 can be wider or narrower in other implementations. (See arrows 132 showing some ways in which the outer sidewalls of the second metal feature 106 can vary.)

Further, in the example of FIG. 1A and FIG. 2, the first metal feature 104 has vertical outer sidewalls, such that an upper portion of the first metal feature 104 has an outermost width that is equal to an outermost width of the base portion 116 of the channel structure. The via 126 under the first metal feature 104 can also have vertical or tapered sidewalls, and the uppermost outer sidewalls of the via 126 are offset from the outer sidewalls of the first metal feature 104 by a lateral spacing, s1.

FIGS. 3A-3C illustrate several top views of FIG. 2's vertical access transistor 105 at different depths. As illustrated, in each of these examples, the cylindrical oxide region 108, the cylindrical channel structure 112, and the cylindrical gate oxide 118 each have an outer perimeter that is circular when viewed from the top view. This circular outer perimeter offers advantages in that it allows for efficient packing of multiple memory cells in a very dense layout, which helps increase memory density compared to previous approaches. Also, the width of the channel structure 112 is w_{ch}=~2π*r (where r is the radius as measured from the central axis 110 to a point in the channel structure 112 where charged carriers flow during operation), which allows for high current-density and fast read/write access times.

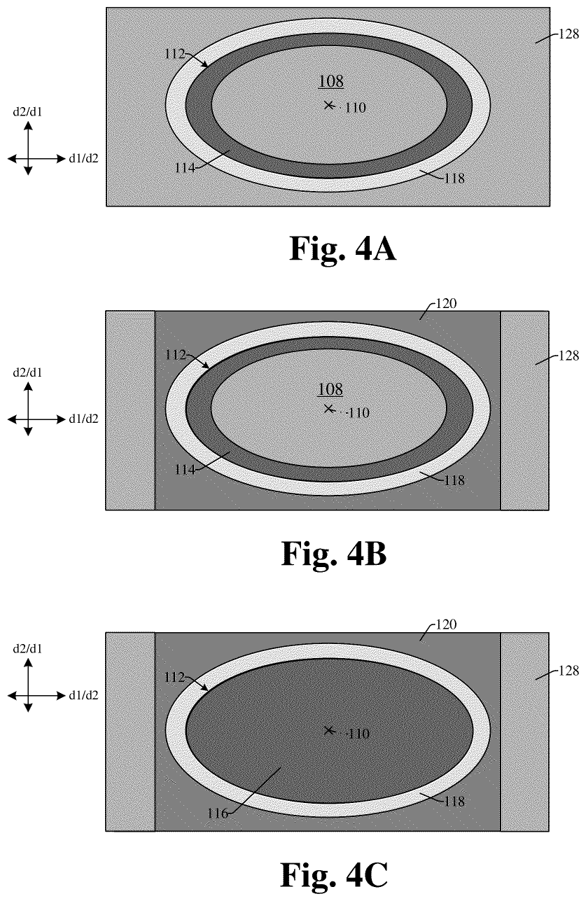

FIGS. 4A-4C illustrate several top views of other embodiments of FIG. 2's vertical access transistor 105 at different depths. As illustrated, in each of these examples, the cylindrical oxide region 108, the cylindrical channel structure 112, and the cylindrical gate oxide 118 each have an outer perimeter that is oval-shaped when viewed from the top views. This oval-shaped outer perimeter offers advantages in that it allows for a wider channel with more current flow, and correspondingly faster read/write access times than a circular channel.

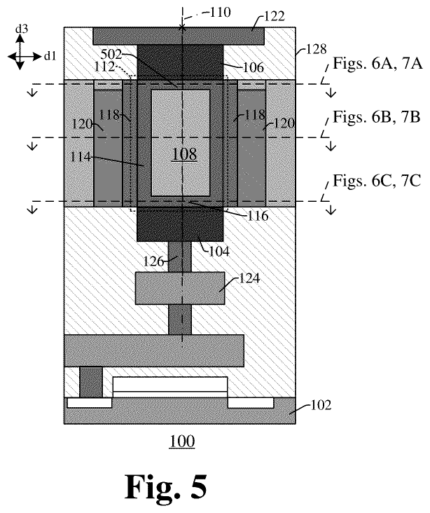

FIG. 5 shows another alternative embodiment where the channel structure further includes a cap portion 502 over the cylindrical oxide region 108. Thus, compared to the example of FIG. 2 where an upper surface of the cylindrical oxide region 108 directly contacts the lower surface of the second metal feature 106, FIG. 5's example has the cap portion 502 separating the upper surface of the cylindrical oxide region 108 from a lower surface of the second metal feature 106. This configuration is advantageous in that it provides a better connection and lower resistance between the channel structure 112 and the second metal feature 106. However, the example of FIG. 2 offers an advantage in that it is more streamlined to manufacture, and thus may offer some cost-savings compared to FIG. 5's example.

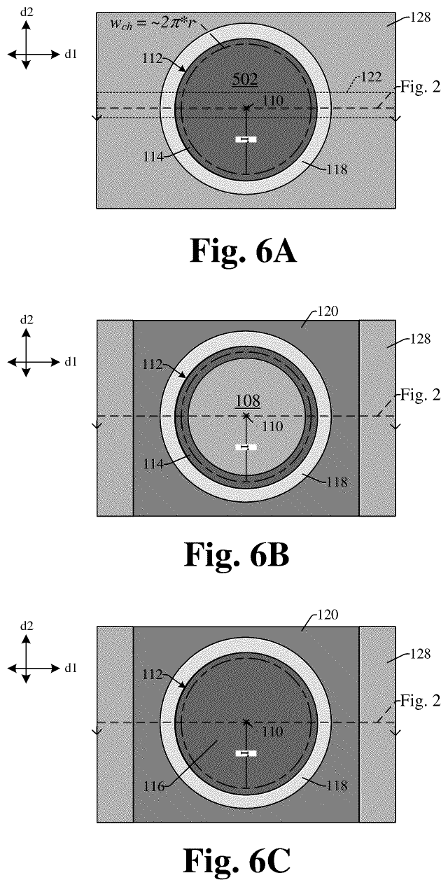

FIGS. 6A-6C illustrate several top views of FIG. 5's vertical access transistor 105 at different depths. As illustrated, in each of these examples, the cylindrical oxide region 108, the cylindrical channel structure 112, and the cylindrical gate oxide 118 each have an outer perimeter that is circular when viewed from the top view. This circular outer perimeter offers advantages in that it allows for efficient packing of multiple memory cells in a very dense layout, which helps increase memory density compared to previous approaches.

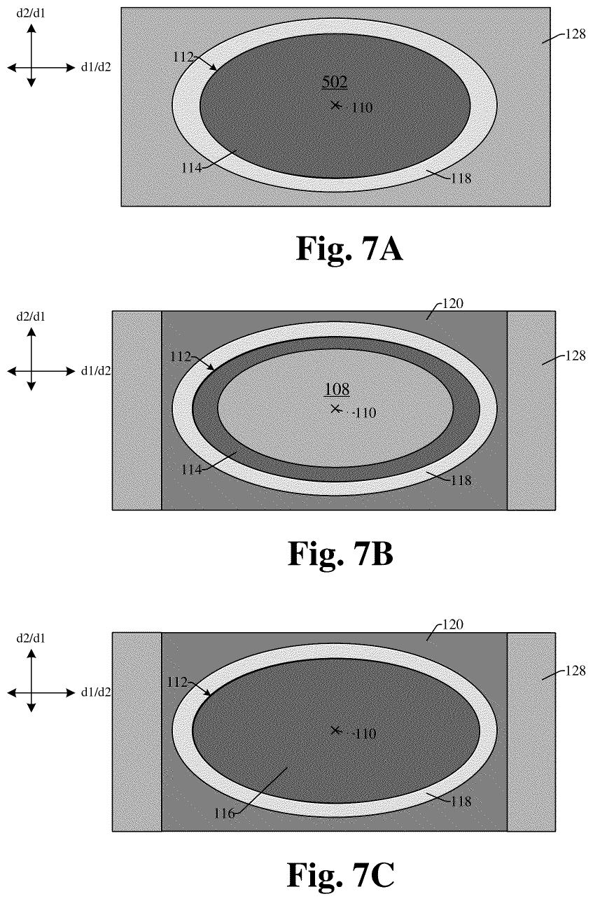

FIGS. 7A-7C illustrate several top views of other embodiments of FIG. 5's vertical access transistor 105 at different depths. As illustrated, in each of these examples, the cylindrical oxide region 108, the cylindrical channel structure 112, and the cylindrical gate oxide 118 each have an outer perimeter that is oval-shaped when viewed from the top views. This oval-shaped outer perimeter offers advantages in that it allows for a wider channel with more current flow, and correspondingly faster read/write access times. It is noted that the term “cylindrical” and variants thereof as used herein can include shapes that have circular top views (e.g., FIGS. 3A-3C and FIGS. 6A-6C); oval-shaped top views (e.g., FIGS. 4A-4C and FIGS. 7A-7C); polygonal top views where the outer sides of the polygon are parallel, non-parallel, and/or have equal or different vertices as viewed from above; and/or polygonal top views with rounded corners. Thus, the term “cylindrical” and variants thereof is not limited merely to the illustrated circular and/or oval top views.

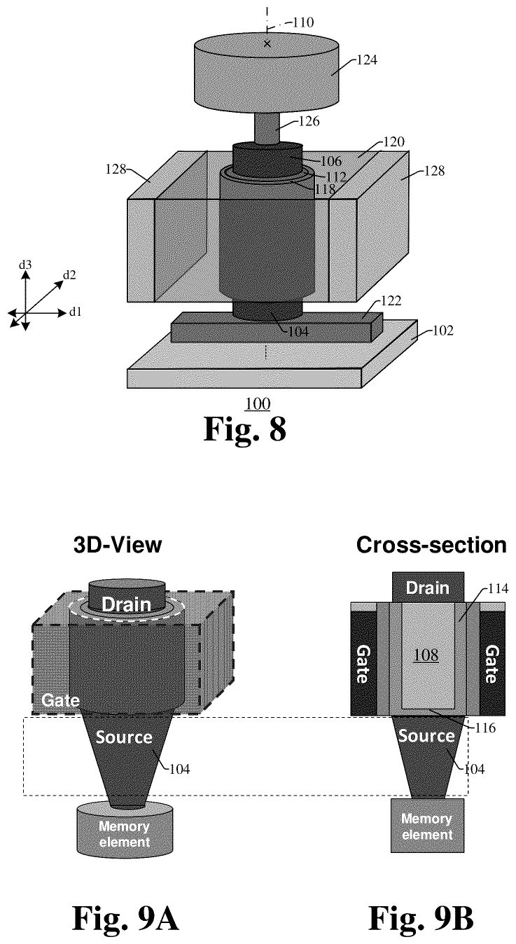

As illustrated in FIG. 8, in some embodiments the orientation of the access transistor and memory element can be “flipped” vertically relative to FIG. 1A. Thus, FIG. 8 shows an example where the bit-line 122 is coupled to the first metal feature 104 and arranged between the first metal feature 104 and the substrate 102; and the memory element 124 is coupled to the second metal feature 106 and arranged over the second metal feature 106. Although FIG. 8 merely shows an example where FIG. 1A's example is “flipped”, the other embodiments and/or examples illustrated and/or described herein can also be flipped in this manner, and thus, all such embodiments fall within the scope of this disclosure.

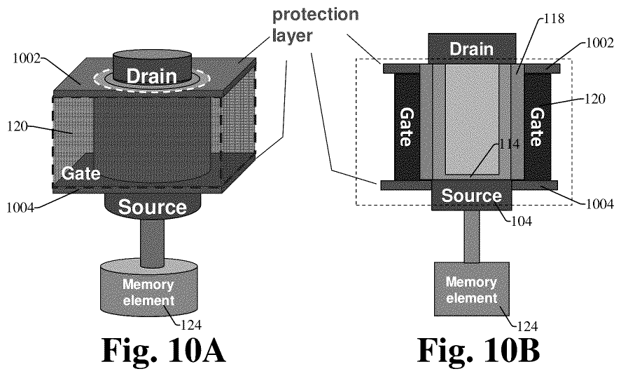

FIGS. 9A-9B illustrate another example where the first metal feature 104 has tapered outer sidewalls such that an upper portion of the first metal feature 104 has an outermost width that is equal to an outermost width of the base portion 116 of the channel structure, and a lower portion of the first metal feature 104 has an outermost width that is less than an outermost width of upper region of the first metal feature 104.

FIGS. 10A-10B illustrate another example where the memory cell includes a protection layer. The protection layer is configured to prevent various atomic species, such as O, N, H, or H₂O from diffusing into the channel structure 112 during processing. An upper portion of the channel protection layer 1002 can extend over an upper surface of the gate electrode 120 and can have an inner sidewall that contacts an outer sidewall of the gate oxide 118. A lower portion of the channel protection layer 1104 can extend under a lower surface of the gate electrode 120 and under a lower surface of the gate oxide 118, and can have an inner sidewall that contacts an outer sidewall of the first metal feature 104. In some embodiments, the channel protection layer can be or comprise Al₂O₃, SiOC, Cr₂O₃, or other materials.

FIGS. 11-14 show various top views of integrated circuits including arrays of memory cells. In general, these examples illustrate a plurality of conductive bit-lines 122 that each extend generally in a first direction, d1 (columns) over the semiconductor substrate, and one or more word-lines 120 that each extend generally in a second direction, d2 (rows) over the semiconductor substrate. The second direction d2 is perpendicular to the first direction d1. Thus, memory elements of the array can be said to be arranged in rows of memory elements (e.g., Row1, Row2) and columns of memory elements (e.g., Column1, Column2, Column3).

In FIG. 11, the memory cells are arranged in two rows and three columns. Respective word-lines 120 extend along respective rows, and respective bit-lines 122 extend along respective columns. Dielectric regions 128 separate respective word-lines from one another. The vertical transistors are arranged in a square-packed configuration, where central axes of the respective vertical access transistors lie on intersection points of two sets of parallel lines that are perpendicular to one another.

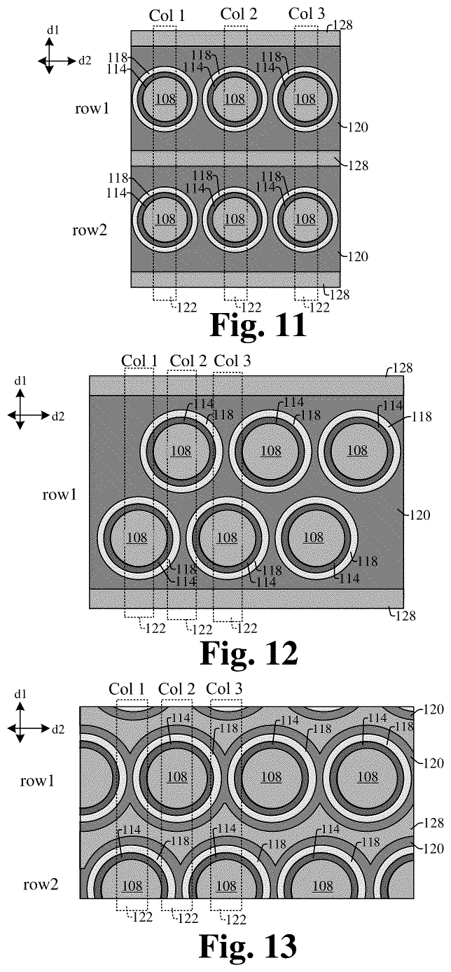

In FIG. 12, a single word-line 120 laterally surrounds multiple rows of memory cells. In this example, central axes of the respective vertical access transistors are arranged in a honeycomb configuration. Thus, central axes of the respective vertical access transistors lie on intersection points of two sets of parallel lines that are perpendicular to one another, and central axes of one row are spaced equally between centers of the adjacent rows.

In FIG. 13, the central axes of the respective vertical access transistors are again arranged in a honeycomb configuration. Here, however, each word-line 120 has an outer sidewall that exhibits a series of circular bumps to surround respective sleeve portion 114 of channel structures and central oxide regions 108 along each row. The dielectric regions 128 also have curved sidewalls, which provides an extremely dense layout.

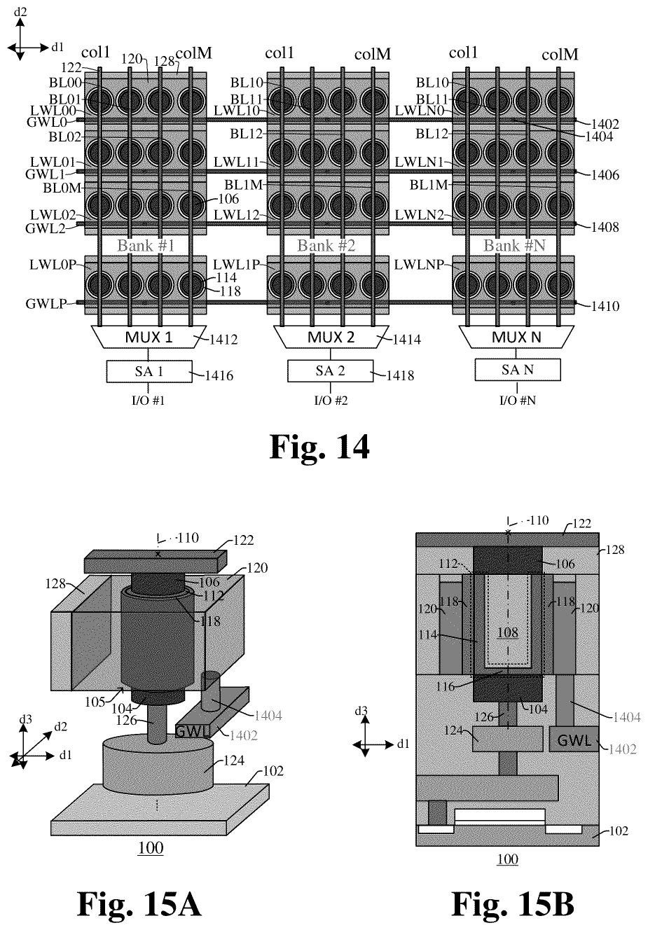

In FIG. 14, an array of access transistors is organized into multiple banks of access transistors (e.g., Bank1, Bank2, . . . , BankN). Each bank of access transistors includes an array of drains 106, sleeve portions 114 of cylindrical channel structures, and cylindrical gate oxide 118 that are spaced apart from one another in the first direction d1 and the second direction d2 to define rows and columns. The conductive word-line 120 for a bank of access transistors is a local conductive word-line that laterally surrounds multiple cylindrical gate oxide structures of the bank of access transistors. In this example, the local word-lines provide lower parasitic capacitance, and therefore can offer faster read/write access times than other approaches.

Global word-lines (GWL) (1402, 1406, 1408, 1410) extend in the first direction d1. Contacts (e.g., 1404) couple a global word-line (e.g., 1402) to multiple local word-lines (LWL) for the multiple respective banks of access transistors. A first group of bit-lines (col 1, . . . , col M of Bank 1) extends over a first bank of access transistors, and a second group of bit-lines (col 1, . . . , col M of Bank2) extends over a second bank of access transistors. A first multiplexer 1412 has input terminals coupled to respective bit-lines of the first group of bit-lines; and a second multiplexer 1414 has input terminals coupled to respective bit-lines of the second group of bit-lines. A first sense-amplifier (SA1) 1416 has an input coupled to the output of the first multiplexor 1412, and a second sense-amplifier (SA2) 1418 has an input coupled to the output of the second multiplexor 1414. The sense amplifiers can each output data at the same time, thereby enabling parallel read operations.

FIG. 15A shows an example of a three-dimensional perspective view of a memory cell with a global word-line 1402 and word-line via 1404 coupling the global word-line 1402 to a local word-line 120. FIG. 15B shows a corresponding cross-sectional view of FIG. 15A.

It will be appreciated that although the various figures illustrate an integrated circuit that includes memory cells, the integrated circuit provided in this disclosure can also include a processor, logic, photodiodes, an image sensor array, other sensors, and/or peripherals. These components can be arranged on a single integrated circuit or die, or can be included on a series of die that are stacked over one another and included in a so-called three-dimensional (3D) IC.

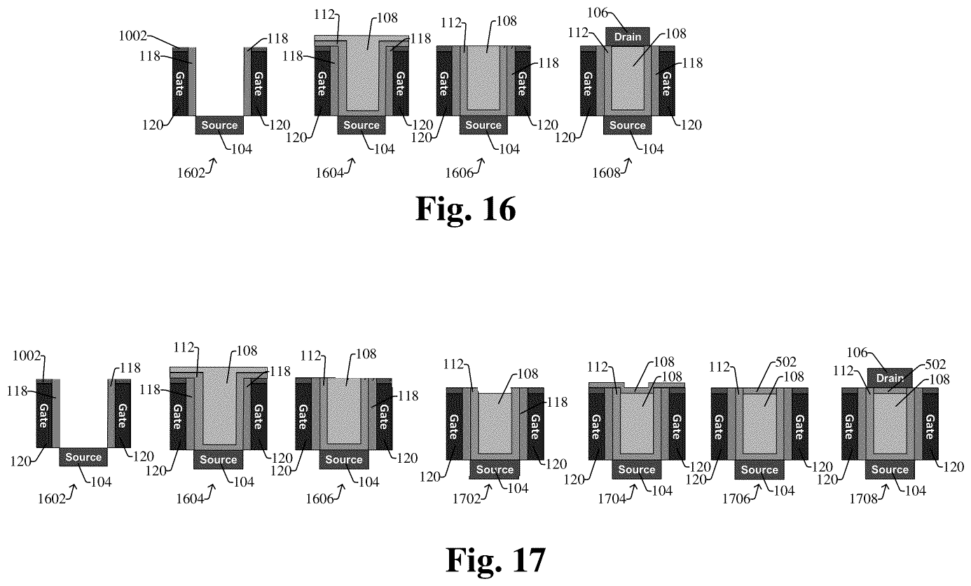

FIGS. 16, 17, and 18-32 illustrate cross-sectional and/or three-dimensional perspective views of some embodiments of various methods of forming an integrated chip having a memory cell with a vertical access transistor. Although FIGS. 16, 17, and 18-32 are described in relation to various methods, it will be appreciated that the structures disclosed in FIGS. 16, 17, and 18-32 are not limited to such methods, but may also stand alone as structures independent of the methods.

FIGS. 16-17 illustrate two methods in a simplified format. One of these methods (FIG. 16) provides a lower cost approach and can be used to form the memory cell illustrated for example in FIG. 2, while the other method (FIG. 17) provides an approach with additional steps that may incur higher cost that can be used to form the memory cell illustrated for example in FIG. 5. Thus, FIG. 17's method can provide an advantage in that it offers better device performance (e.g., higher current density and therefore faster read/write access times), while FIG. 16's method may provide a different advantage in that it is cheaper.

In FIG. 16, a source 104 is formed, and a gate electrode 120 is formed over the source 104, leaving a cylindrical opening (see 1602). A channel protection layer 1002 can also be formed over the gate electrode 120 (see 1602). A gate oxide 118 is formed along sidewalls of the gate electrode in the cylindrical opening; a channel structure 112 is then formed along a top surface of the source 104, along inner sidewalls and upper surfaces of the gate oxide 118, and over the gate electrode 120; and a dielectric core 108 is then formed to fill the remainder of the cylindrical opening (see 1604). The material of the dielectric core can also typical extend over the upper surface of the structure. A chemical mechanical planarization (CMP) is then carried out to planarize the structure, and can stop on the channel protection layer 1002 (see 1606). Then, a drain 106 is formed over the planarized surface (see 1608). Thus, the resulting channel structure 112 has a so-called “macaroni” shape whereby it has a hollow central area that is filled by the dielectric core 108. In other embodiments, the channel structure 112 could be a continuous, solid cylindrical structure that entirely fills the cylindrical opening in 1602, which would eliminate the need for the dielectric fill 108 and thereby simplify the manufacturing process. However, the illustrated “macaroni” shape provides the device with better channel control because the electric field from the gate electrode effectively turns off the channel when the thickness of the channel is less than 10 nm, as measured normal to the sidewall of the gate oxide 118. In contrast, if the cylindrical opening was filled completely with channel material 112, the transistor leakage current would be increased because the gate electrode cannot successfully turn-off the central region channel. Therefore, the illustrated embodiment showing the “macaroni” shape is advantageous in that it provides better device performance.

In FIG. 17, a source 104, gate electrode 120, gate oxide 118, initial channel structure 112, and dielectric core 108 are formed as in FIG. 16 (see 1602, 1604, 1606). Then, however, an upper portion of the dielectric core is recessed using a selective etch (see 1702). An upper cap portion of the channel region is then formed to fill the remainder of the cylindrical opening (see 1704). A chemical mechanical planarization (CMP) is then carried out to planarize the structure (see 1706). Then, a drain 106 is formed over the planarized surface.

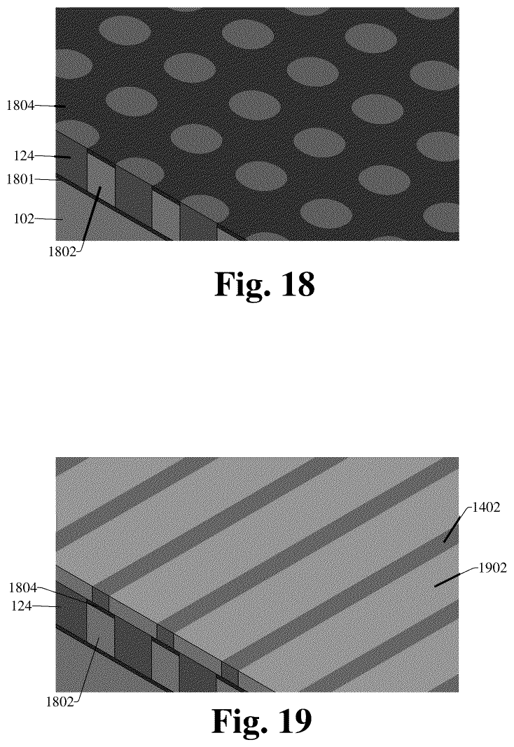

FIGS. 18-32 illustrate a more detailed method in accordance with some embodiments.

In FIG. 18, an array of memory elements 124 are formed over a semiconductor substrate 102. The memory elements 124 can take various forms, but often are arranged within a back end of line (BEOL) interconnect structure over the semiconductor substrate 102. A dielectric structure 1802, such as silicon dioxide or low-k dielectric material, can separate the memory elements 124. A first stopping layer 1804, such as an etch stop layer that is made of silicon nitride, or silicon carbide, or silicon carbonitride, among others, can also be present. In some embodiments, a stopping layer 1801 can also be present under the memory elements 124.

In some embodiments, the semiconductor substrate 102 can be a bulk monocrystalline silicon substrate or a semiconductor-on-insulator (SOI) substrate (e.g., silicon on insulator substrate). The semiconductor substrate can also be a binary semiconductor substrate (e.g., GaAs), a tertiary semiconductor substrate (e.g., AlGaAs), or a higher order semiconductor substrate, for example. In many instances, the semiconductor substrate manifests as a semiconductor wafer, and can have a diameter of 1-inch (25 mm); 2-inch (51 mm); 3-inch (76 mm); 4-inch (100 mm); 5-inch (130 mm) or 125 mm (4.9 inch); 150 mm (5.9 inch, usually referred to as “6 inch”); 200 mm (7.9 inch, usually referred to as “8 inch”); 300 mm (11.8 inch, usually referred to as “12 inch”); 450 mm (17.7 inch, usually referred to as “18 inch”); for example. After processing is completed, such a wafer can optionally be stacked with other wafers or die, and is then singulated into individual die which correspond to individual integrated circuits. Each memory element 124 can correspond to a resistive random access memory (RRAM), magnetic random access memory MRAM, phase change random access memory (PCRAM), ferroelectric tunnel junction (FTJ) memory, and/or a metal-insulator metal (MIM) capacitor in the BEOL interconnect structure, or can even be a trench capacitor disposed in the semiconductor substrate 102, among others.

In FIG. 19, global word-lines 1402 are formed over the memory elements 124. This can be achieved by depositing a continuous sheet of first dielectric film 1902, such as silicon dioxide or a low-k dielectric over an upper surface of the memory elements 124. The first dielectric film 1902 is then patterned, for example by forming one or more photoresist masks over the film and performing an etch with the mask(s) in place to form trenches in the dielectric film. Metal is then formed to fill the trenches and extend over the structure, and a CMP process is carried out to yield the structure including the global word-lines 1402 illustrated in FIG. 19.

In FIG. 20, a second dielectric film 2002 is deposited, and a third stopping layer 2004 is formed. The second dielectric film 2002 is patterned using lithography, and an etch is performed to form memory element via openings. Metal is then formed over the structure, and a CMP process is carried out to yield the structure including a memory element via 126 illustrated in FIG. 20.

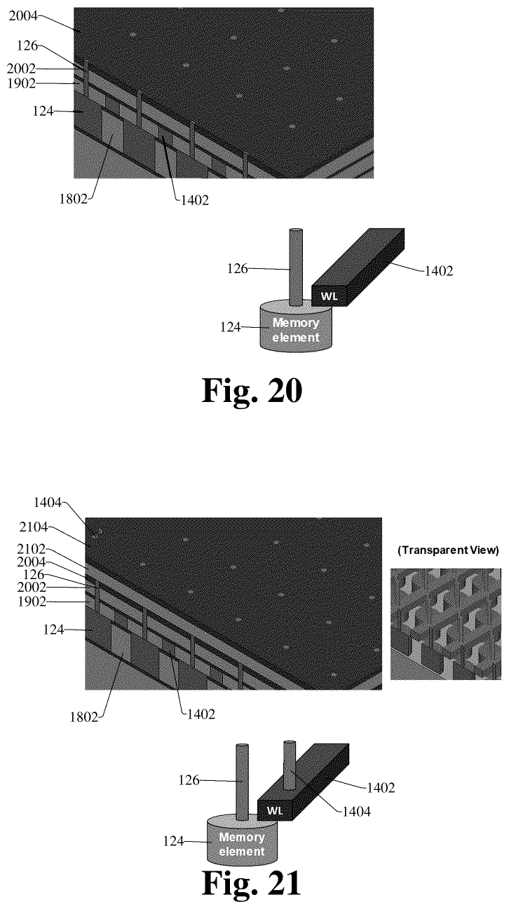

In FIG. 21, a third dielectric film 2102 is deposited, and a fourth stopping layer 2104 is formed. The third dielectric film is patterned using lithography, and an etch is performed to form word-line via openings. Metal is then formed over the structure, and a CMP process is carried out to yield the structure including a word-line via 1404 illustrated in FIG. 21.

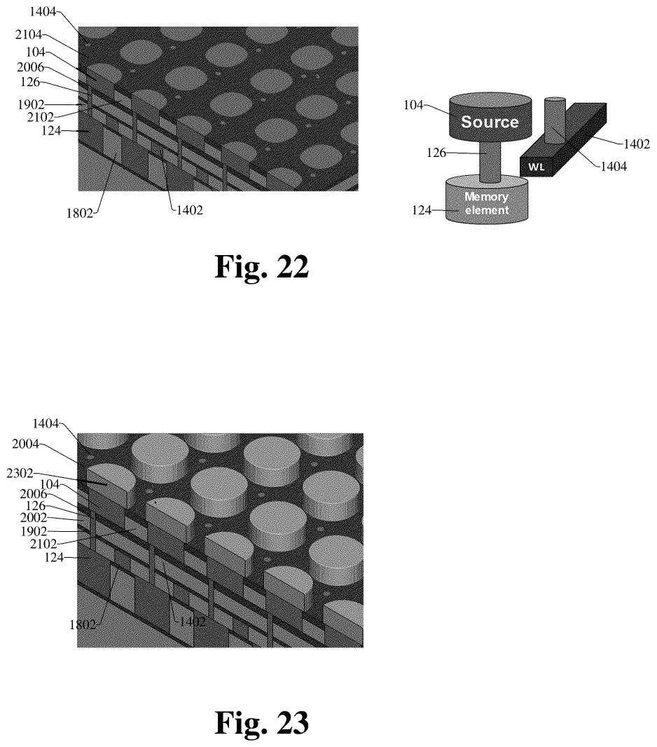

In FIG. 22, the third dielectric film 2102 and third stopping layer 2014 are again patterned using lithography, and an etch is performed to form source openings. Metal is then formed over the structure, and a CMP process is carried out to yield the structure including a source 104 illustrated in FIG. 22.

In FIG. 23, a sacrificial film is deposited. The sacrificial film is patterned using lithography, and an etch is performed to leave sacrificial cylinders 2302 in place over the sources. In some embodiments, the sacrificial film is a nitride, such as silicon nitride.

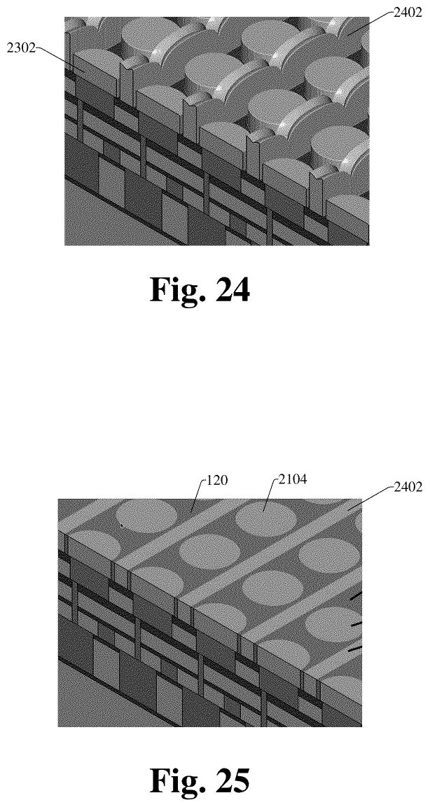

In FIG. 24, an oxide film is deposited. The oxide film is patterned using lithography, and an etch is performed to leave oxide lines 2402 extending between adjacent rows of sacrificial cylinders 2302. In some embodiments, the oxide film is a silicon dioxide.

In FIG. 25, a metal layer is formed over the structure to form local word-lines. In some embodiments, the metal layer is a copper, aluminum, nickel, titanium, and/or tantalum. A CMP process is carried out and stops on the sacrificial cylinders, thereby yielding the illustrated structure including word-lines 120 (which may be local word-lines arranged in banks in some embodiments). The word-lines 120 are spaced apart from one another by planarized oxide lines 2402. The local word-lines 120 also laterally surround the sacrificial cylinders 2302.

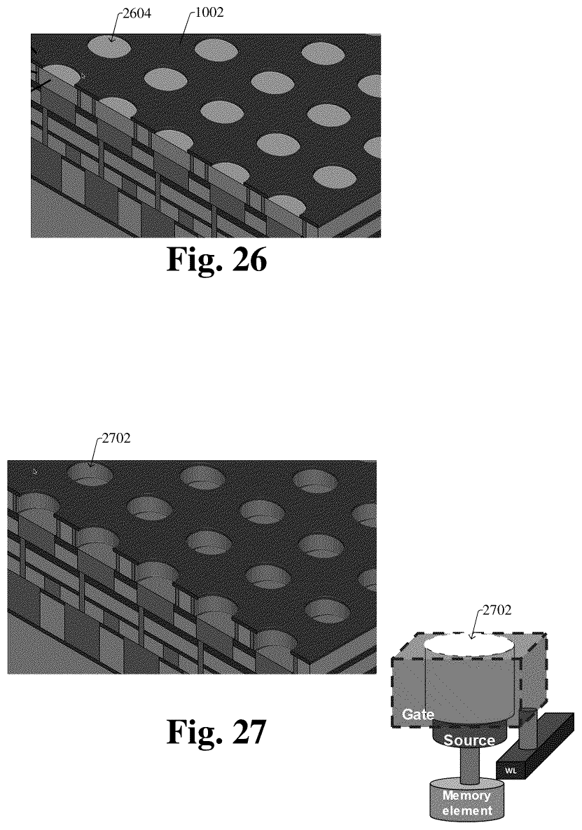

In FIG. 26, a protective layer 2602, such as an aluminum oxide layer, is formed. Lithography is used to form a photomask over the protective layer, wherein the photomask includes respective openings over the respective sacrificial cylinder structures 2302. The protective layer 2602 is then etched to form shallow openings 2604 that stop on the sacrificial cylinders.

In FIG. 27, the sacrificial cylinder structures are removed using another etch (e.g., a wet etch), thereby forming cylindrical openings 2702 over the sources. The cylindrical openings 2702 also expose inner sidewalls of the word-lines 120.

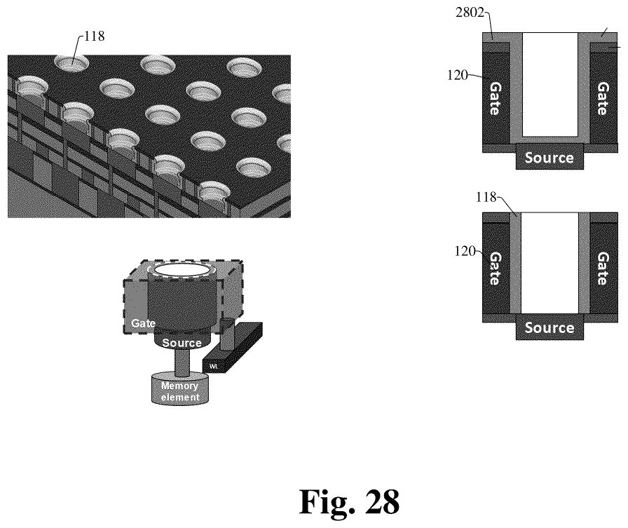

In FIG. 28, a gate oxide liner 2802 is formed to cover upper surfaces of the sources 104 and the inner sidewalls of the word-lines 120. For example, the gate oxide liner 2802 can be silicon dioxide or a low-k dielectric that is deposited on the structure. After being deposited, a vertical etch, such as a plasma etch or dry etch, is used to remove and/or breakthrough the gate oxide liner 2802 to form gate oxide 118. Thus, the etch re-exposes the source 104 while leaving remaining portions of the gate oxide 118 on the inner sidewalls of the word-lines 120.

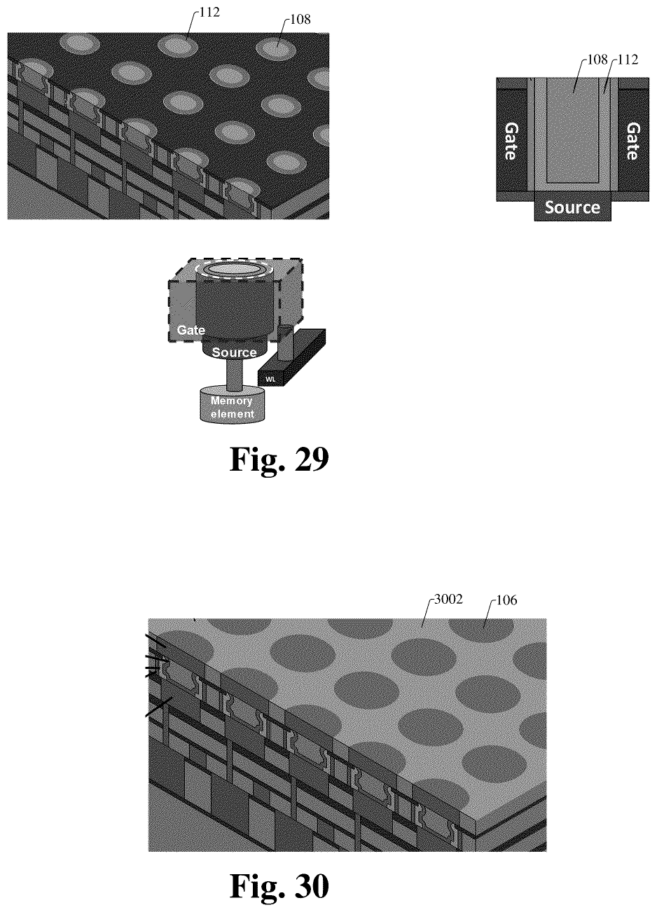

In FIG. 29, channel material 112 is deposited on the upper surface of source and inner sidewalls of the gate oxide, and over the upper surface of the structure. The channel material can comprise indium tungsten oxide (IWO), indium tin oxide (ITO), indium gallium zinc oxide (IGZO), or another semiconductor material. Then, after the channel material is formed, an oxide region 108, such as SiO2 is formed to fill the remainder of the cylindrical openings. A CMP process is then performed and stops on the protection layer 2602. Using silicon dioxide to fill the cylindrical openings can help with manufacturing reliability, in that the memory array tends to have a uniform physical rigidity over its area so this CMP process and subsequent CMP processes provide a very level/flat profile, with very few hillocks or dishing over the array.

In FIG. 30, an oxide film 3002 is deposited. The oxide film is patterned using lithography, and an etch is performed to leave drain openings in the oxide film. Then, a metal layer is formed over the structure to form drains. In some embodiments, the metal layer is a copper, aluminum, nickel, titanium, and/or tantalum. A CMP process is carried out to yield the illustrated structure including drains 106 that are isolated from one another by the oxide film.

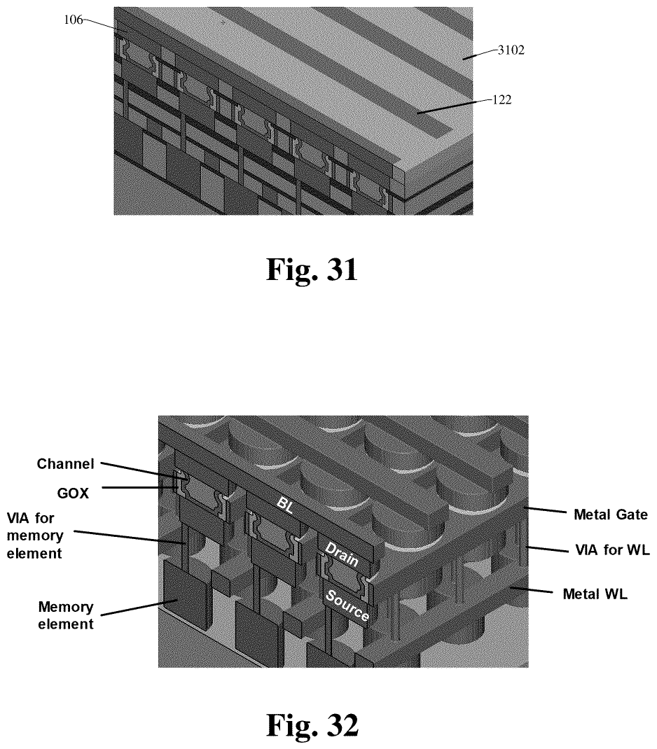

In FIG. 31, bit-lines 122 are formed over the drains. This can be achieved by depositing a continuous sheet of dielectric film 3102, such as silicon dioxide or a low-k dielectric over an upper surface of the drains. The dielectric film 3102 is then patterned, for example by forming one or more photoresist masks over the film and performing an etch with the mask(s) in place to form trenches in the dielectric film. Metal is then formed to fill the trenches and extend over the structure, and a CMP process is carried out to yield the structure including the bit-lines 122 illustrated in FIG. 31.

FIG. 32 provides a transparent view of the memory structure formed in FIG. 31. Thus, the memory structure illustrated in FIG. 32 is merely the memory structure of claim 31 with the various dielectric layers removed/transparent so the various conductive features and operable coupling of the various circuit features can be seen.

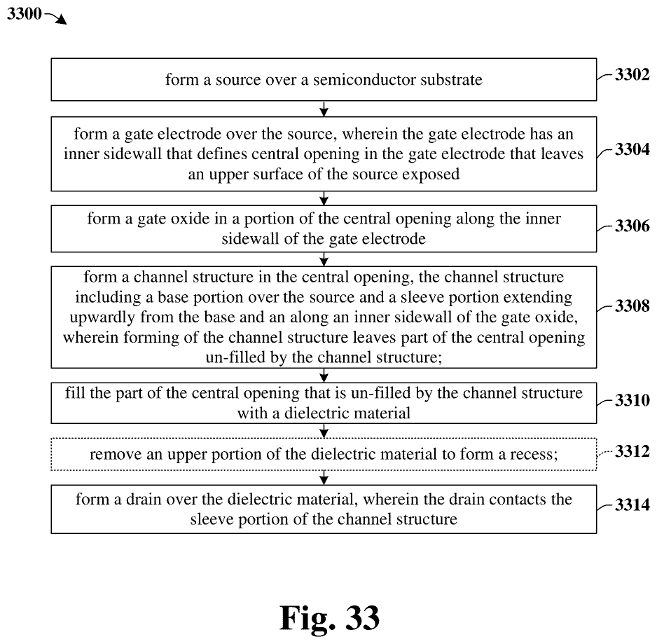

FIG. 33 illustrates a flow diagram of some embodiments of a method 3300 of forming a memory cell and/or memory array according to some embodiments. While method 3300 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 3302, a source is formed over a semiconductor substrate. For example, FIG. 22 can depict some examples of 3302.

At 3304, a gate electrode is formed over the source. The gate electrode has an inner sidewall that defines a central opening in the gate electrode that leaves an upper surface of the source exposed. For example, FIG. 25 can depict some examples of 3304.

At 3306, a gate oxide is formed in a portion of the central opening along the inner sidewall of the gate electrode. For example, FIG. 28 can depict some examples of 3306.

At 3308, a channel structure is formed in the central opening. The channel structure includes a base portion over the source and a sleeve portion extending upwardly from the base and an along an inner sidewall of the gate oxide. Forming of the channel structure leaves part of the central opening un-filled by the channel structure. For example, FIG. 16, FIG. 17, and/or FIG. 29 can depict some examples of 3308.

At 3310, the part of the central opening that is un-filled by the channel structure is filled with a dielectric material. For example, FIG. 16, FIG. 17, and/or FIG. 29 can depict some examples of 3310.

At 3312, which is optional, an upper portion of the dielectric material is removed to form a recess. The recess is then filled with a capping structure that can have the same material composition as the channel structure. For example, FIG. 17 (1702-1706) can depict some examples of 3312.

At 3314, a drain is formed over the dielectric material. The drain contacts the sleeve portion of the channel structure. For example, FIG. 16, FIG. 17, and/or FIG. 30 can depict some examples of 3314.

Therefore, the present disclosure relates to new memory devices and methods of manufacturing memory devices that include a vertical access transistor for a high memory density.

Accordingly, in some embodiments, the present disclosure relates to an integrated circuit including a semiconductor substrate. A first metal feature is disposed over the semiconductor substrate, and a second metal feature is disposed over the first metal feature. A cylindrical oxide region has a central axis that extends perpendicularly between an upper surface of the first metal feature and a lower surface of the second metal feature. A channel structure is disposed between the first metal feature and the second metal feature. The channel structure includes a base portion and a sleeve portion. The base portion separates the first metal feature from the cylindrical oxide region, and the sleeve portion extends from an edge region of the base portion to the second metal feature. The sleeve portion concentrically surrounds the cylindrical oxide region. A cylindrical gate oxide concentrically surrounds the channel structure. A gate electrode concentrically surrounds the cylindrical gate oxide. The cylindrical gate oxide separates the gate electrode from the channel structure.

Accordingly, in some embodiments, the present disclosure relates to an integrated circuit. The integrated circuit includes a semiconductor substrate; a plurality of conductive bit-lines that each extend generally in a first direction over the semiconductor substrate; and a first array of memory elements arranged over the semiconductor substrate. The first array of memory elements is organized in rows of memory elements and columns of memory elements. The memory elements in each column are aligned in the first direction and the memory elements of each row are aligned in a second direction that is perpendicular to the first direction. A second array of access transistors is disposed over or under the first array the memory elements. An access transistor of the second array has an axis that intersects a bit-line and a memory element of the first array, and the axis is perpendicular to the first direction and the second direction. The access transistor includes a cylindrical oxide region having a central axis aligned on the axis of the access transistor when viewed from a cross-sectional view. A cylindrical channel structure concentrically surrounds the cylindrical oxide region when viewed from a top view. A cylindrical gate oxide concentrically surrounds the cylindrical channel structure when viewed from the top view. A conductive word-line extends generally in the second direction and laterally surrounds the cylindrical gate oxide.

In other embodiments, the present disclosure relates to a method. A source is formed over a semiconductor substrate. A gate electrode is formed over the source. The gate electrode has an inner sidewall that defines a central opening in the gate electrode and that leaves an upper surface of the source exposed. A gate oxide is formed in a portion of the central opening along the inner sidewall of the gate electrode. A channel structure is formed in the central opening. The channel structure includes a base portion over the source and a sleeve portion extending upwardly from the base and an along an inner sidewall of the gate oxide. Forming of the channel structure leaves part of the central opening un-filled by the channel structure. The part of the central opening that is un-filled by the channel structure is filled with a dielectric material. A drain is formed over the dielectric material. The drain contacts the sleeve portion of the channel structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a semiconductor substrate;
a first metal feature disposed over the semiconductor substrate;
a second metal feature disposed over the first metal feature;
a cylindrical oxide region having a central axis that extends perpendicularly between an upper surface of the first metal feature and a lower surface of the second metal feature when viewed in cross-section;
a channel structure disposed between the upper surface of the first metal feature and the lower surface of the second metal feature, the channel structure including a base portion and a sleeve portion, the base portion separating the upper surface of the first metal feature from a lower surface of the cylindrical oxide region when viewed in the cross-section, and the sleeve portion extending from an edge region of the base portion to the lower surface of the second metal feature when viewed in the cross-section, and the sleeve portion concentrically surrounding the cylindrical oxide region when viewed from a top view;
a cylindrical gate oxide concentrically surrounding the channel structure when viewed from the top view; and
a gate electrode concentrically surrounding the cylindrical gate oxide when viewed from the top view, the cylindrical gate oxide separating the gate electrode from the channel structure.

2. The integrated circuit of claim 1, wherein the first metal feature has outer sidewalls that are aligned with outer sidewalls of the sleeve portion of the channel structure.

3. The integrated circuit of claim 1, further comprising:
a memory element coupled to the first metal feature and arranged between the first metal feature and the semiconductor substrate; and
a bit-line coupled to the second metal feature, and arranged over the second metal feature.

4. The integrated circuit of claim 1, wherein the first metal feature has vertical outer sidewalls such that an upper portion of the first metal feature has an outermost width that is equal to an outermost width of the base portion of the channel structure.

5. The integrated circuit of claim 1, wherein the cylindrical oxide region, the channel structure, and the cylindrical gate oxide each have an outer perimeter that is circular when viewed from the top view.

6. The integrated circuit of claim 1, wherein the cylindrical oxide region, the channel structure, and the cylindrical gate oxide each have an outer perimeter that is an oval when viewed from the top view.

7. The integrated circuit of claim 1, wherein the channel structure further comprises a cap portion over the cylindrical oxide region, the cap portion separating the an upper surface of the cylindrical oxide region from a lower surface of the second metal feature when viewed in the cross-section.

8. The integrated circuit of claim 1, further comprising:
a bit-line coupled to the first metal feature and arranged between the first metal feature and the semiconductor substrate; and
a memory element coupled to the second metal feature, and arranged over the second metal feature.

9. The integrated circuit of claim 1, wherein the first metal feature has tapered outer sidewalls such that an upper portion of the first metal feature has an outermost width that is equal to an outermost width of the base portion of the channel structure, and a lower portion of the first metal feature has an outermost width that is less than an outermost width of upper region of the first metal feature.

10. The integrated circuit of claim 1, further comprising:
a protection layer comprising aluminum oxide arranged over the upper surface of the gate electrode, the protection layer having an inner sidewall that abuts an outer sidewall of the cylindrical gate oxide.

11. An integrated circuit, comprising:
a semiconductor substrate;
a plurality of conductive bit-lines that each extend generally in a first direction over the semiconductor substrate;
a first array of memory elements arranged over the semiconductor substrate, wherein the first array of memory elements is organized in rows of memory elements and columns of memory elements, wherein the memory elements in each column are aligned in the first direction and the memory elements of each row are aligned in a second direction that is perpendicular to the first direction;
a second array of access transistors disposed over or under the first array the memory elements, wherein an access transistor of the second array has an axis that extends in a third direction and intersects a bit-line and a memory element of the first array, and the axis is perpendicular to the first direction and the second direction, wherein the access transistor comprises:
a cylindrical oxide region having a central axis aligned on the axis of the access transistor when viewed from a cross-sectional view;
a cylindrical channel structure concentrically surrounding the cylindrical oxide region when viewed from a top view;
a cylindrical gate oxide concentrically surrounding the cylindrical channel structure when viewed from the top view; and
a conductive word-line that extends generally in the second direction and laterally surrounds the cylindrical gate oxide.

12. The integrated circuit of claim 11, further comprising:
a base channel structure arranged on a first end of the cylindrical channel structure and covering a first end of the cylindrical oxide region when viewed in cross-section.

13. The integrated circuit of claim 12, further comprising:
a capping channel structure arranged on a second end of the cylindrical channel structure and covering a second end of the cylindrical oxide region when viewed in cross-section.

14. The integrated circuit of claim 11, wherein the second array of access transistors is organized into multiple banks of access transistors; wherein each bank of access transistors comprises:
an array of cylindrical oxide regions having respective axes aligned in the third direction, the cylindrical oxide regions spaced apart from one another in the first direction and the second direction to define rows and columns;
cylindrical channel structures concentrically surrounding the cylindrical oxide regions, respectively, when viewed from the top view;
cylindrical gate oxide structures concentrically surrounding the cylindrical channel structures, respectively, when viewed from the top view; and
wherein the conductive word-line for a bank of access transistors is a local conductive word-line that laterally surrounds multiple cylindrical gate oxide structures of the bank of access transistors.

15. The integrated circuit of claim 14, further comprising:
a global word-line extending in the second direction and being coupled to multiple local word-lines for the multiple respective banks of access transistors.

16. The integrated circuit of claim 14, wherein a first group of bit-lines extends over a first bank of access transistors, and a second group of bit-lines extends over a second bank of access transistors, and further comprising:
a first multiplexer having input terminals coupled to respective bit-lines of the first group of bit-lines; and
a second multiplexer having input terminals coupled to respective bit-lines of the second group of bit-lines.

17. A method, comprising:
forming a source over a semiconductor substrate;
forming a gate electrode over the source, wherein the gate electrode has an inner sidewall that defines central opening in the gate electrode that leaves an upper surface of the source exposed;
forming a gate oxide in a portion of the central opening along the inner sidewall of the gate electrode;
forming a channel structure in the central opening, the channel structure including a base portion over the source and a sleeve portion extending upwardly from the base portion and an along an inner sidewall of the gate oxide, wherein forming of the channel structure leaves part of the central opening un-filled by the channel structure;
filling the part of the central opening that is un-filled by the channel structure with a dielectric material; and
forming a drain over the dielectric material, wherein the drain contacts the sleeve portion of the channel structure.

18. The method of claim 17, further comprising:
prior to forming the drain, removing an upper portion of the dielectric material to form a recess;
filling the recess with a capping structure, the capping structure having the same material composition as the channel structure; and
wherein the drain is formed over the capping structure.

19. The method of claim 18, wherein the same material composition comprises at least one the following: indium tungsten oxide (IWO), indium tin oxide (ITO), or indium gallium zinc oxide (IGZO).

20. The method of claim 17, wherein the dielectric material is a cylinder having a central axis that extends perpendicularly between an upper surface of the source and a lower surface of the drain, wherein the channel structure is a cylinder that concentrically surrounds the dielectric material, wherein the gate oxide is a cylinder that concentrically surrounds the channel structure, and wherein the gate electrode laterally surrounds the gate oxide such that the gate oxide separates the gate electrode from the channel structure.
